(19) United States
(12) Patent Application Publication
(10) Pub. No.: US 2009/0302306 A1
(43) Pub. Date: Dec. 10, 2009

(54) Nano Electronic Device and Fabricating Method of The Same

(76) Inventors: Wan-Soo Yun, Daejeon (KR); Sung-Oong Kang, Chungcheong-namdo (KR); Hyung-Ju Park, Busan (KR)

Correspondence Address: CLARK & BRODY, 1090 VERMONT AVENUE, NW, SUITE 250, WASHINGTON, DC, 20005, US

(21) Appl. No.: 12/223,009

(22) PCT Filed: Apr. 5, 2006
(86) PCT No.: PCT/KR2006/001251

§ 371 Date: Nov. 25, 2008

(30) Foreign Application Priority Data
Jan. 9, 2006 (KR) 10-2006-0005994

(51) Int. Cl. H01L 29/775; H01L 29/12; H01L 21/02; H01L 21/336

(52) U.S. Cl. 257/12; 438/3; 257/295; 977/762; 977/700; 257/E21.002; 257/E29.068; 257/E29.245

(57) ABSTRACT

Disclosed herein are a nano electronic device and a method of fabricating the same. The nano electronic device includes a ferroelectric nano-structure and a semiconducting nano-wire. Polarization formed on the ferroelectric nano-structure is utilized.

### TECHNICAL FIELD

The present invention is related to a nano electronic device and a method of fabricating the same. In particular, the invention is related to a nano electronic device using nano electric polarization of a ferroelectric nano-structure and a method of fabricating the same.

### BACKGROUND ART

Ferroelectric materials have been used in high capacity condensers, sound wave detectors, ceramic sensors, piezoelectric actuators and the like. Recently the ferroelectric materials are drawing attentions as a core material of non-volatile memory device using ferroelectricity. The ferroelectric material has a spontaneous electric polarization, whose orientation can be controlled by an external electric field. This electric polarization can be utilized in non-volatile memory devices.

The method of fabricating a transistor using the ferroelectric material has been studied since 1950s (U.S. Pat. Nos. 2,791,758, 2,791,759, 2,791,760, and 2,791,761). In recent years, many research results and patents have been reported with respect to methods of fabricating non-volatile memory devices using a ferroelectric thin film (Science, vol. 276, No. 1, 238 page, 1997; Science, Vol. 276, No. 16, 1100 page, 1997; Nature, vol. 401, No. 14, 682 page, 1999; U.S. Pat. Nos. 6,151,240, 6,623,989, 6,278,630, 6,301,145, 6,663,989, and 6,893,886).

As electronic devices including a memory device are miniaturized, the size and thickness of ferroelectric material also become smaller and thinner. This scaling-down may cause a change in the ferroelectricity. That is, it may change the physical properties such as the critical size for ferroelectricity, phase transition temperature, retention time of ferroelectricity, or the like. Fabrication of a new-type memory device using these property changes is drawing attentions (Nano. Lett. Vol. 2, No. 5, 447 page, 2002).

Accordingly, in recent years, many studies on nanoscale ferroelectricity have been reported focusing on a thin-film form of specimen (Phys. Rev. Lett. Vol. 89, No. 9, 097601-1 page, 2002; Nature, Vol. 422, No. 3, 506 page, 2003; Science, Vol. 304, No. 11, 1650 page, 2004).

Recently, methods of effectively synthesizing a high quality ferroelectric nano-wire have been published (US Patent Application No. 2002-483935; Korean Patent No. 04-58415; J. Am. Chem. Soc., Vol. 124, No. 7, 1186 page, 2002; J. Am. Chem. Soc., Vol. 125, No. 51, 15718 page, 2003), and many attempts have been made in order to develop functional nano-devices using the ferroelectric material.

However, methods of fabricating a memory device using the characteristics of the ferroelectric nano-wire have not yet been reported. The nano-structure showing the spontaneous polarization of ferroelectric materials can contribute to realization of an unprecedented a high-capacity memory device.

### DISCLOSURE

### Technical Problem

Accordingly, the present invention has been made in order to solve the above problems occurring in the prior art, and it is an object of the invention to provide a nano electronic device using electric polarization through an hybrid configuration of dissimilar nano-structures.

Another object of the invention is to provide a method of fabricating a nano electronic device, in which a ferroelectric material is synthesized into a nano-structure and the ferroelectric nano-structure is controlled so as to form a junction with a semiconducting nano-wire.

A further object of the invention is to provide a non-volatile memory device and information storage technologies having at least one ferroelectric nano-structure using nano electric polarization.

### Technical Solution

In order to accomplish the above objects, according to one aspect of the invention, there is provided a nano electronic device comprising at least one ferroelectric nano-structure and at least one semiconducting nano-wire, wherein electric polarization formed in the ferroelectric nano-structure is utilized.

The semiconducting nano-wire forms at least one junction with the ferroelectric nano-structure, or is placed in a distance from the ferroelectric nano-structure so as for the electric polarization to be induced in the ferroelectric nano-structure by an electric field. In the nano device according to the invention, a voltage is applied to a substrate or a gate electrode to form polarization in the ferroelectric nano-structure. The ferroelectric polarization is detected by measuring the conductivity of the semiconducting nano-wire between a source electrode and a drain electrode connected to both ends of the semiconducting nano-wire. The position of the gate electrode is not necessarily specifically restricted as long as it is close enough to induce polarization to the ferroelectric nano-structure.

The ferroelectric nano-structure used in the nano device of the invention is not necessarily specifically restricted, but may be formed of a perovskite barium titanate. The ferroelectric nano-structure may have a diameter of 1 nm˜10 μm and a length of 10 nm˜100 μm.

The semiconducting nano-wire adopted for the nano device of the invention can employ a material capable of inducing an electric polarization in the ferroelectric nano-structure, and may include a silicon nano-wire.

In addition, the ferroelectric nano-structure and the semiconducting nano-wire may be placed on a substrate having a pattern formed thereon or no pattern. An insulation film may be formed on the substrate. The order of forming the ferroelectric nano-structure and semiconducting nano-wire is not necessarily specifically restricted. That is, the ferroelectric nano-structure may be first formed on the insulation film of the substrate, or the semiconducting nano-wire may be first formed.

A nano electronic device according to the first embodiment of the invention comprises: at least one ferroelectric nano-structure formed on a substrate; at least one semiconducting nano-wire forming at least one junction with the ferroelectric nano-structure; and a source electrode and a drain electrode formed at both ends of the semiconducting nano-wire, wherein a gate voltage can be applied to the substrate.

A nano electronic device according to the second embodiment of the invention comprises: at least one semiconducting nano-wire formed on a substrate; a source electrode and a drain electrode formed at both ends of the semiconducting nano-wire; at least one ferroelectric nano-structure forming at least one junction with the semiconducting nano-wire; an insulation layer formed on the semiconducting nano-wire and the ferroelectric nano-structure; and at least one gate electrode placed on the insulation layer.

In addition, a nano electronic device according to the third embodiment of the invention comprises: at least one semiconducting nano-wire and at least one ferroelectric nano-structure formed on a substrate so as to be close to each other; a source electrode and a drain electrode formed at both ends of the semiconducting nano-wire; and at least one gate electrode formed at a position to be able to induce polarization to the ferroelectric nano-structure.

According to another aspect of the invention, there is provided a method fabricating a nano electronic device, the method comprising the steps of: forming at least one ferroelectric nano-structure on a substrate; forming at least one semiconducting nano-wire on the ferroelectric nano-structure so as to form at least one junction; and forming a source electrode and a drain electrode at both ends of the semiconducting nano-wire, wherein a gate voltage can be applied to the substrate.

According to a further aspect of the invention, there is provided a method of fabricating a nano electronic device, the method comprising the steps of: forming at least one semiconducting nano-wire on a substrate and forming a source electrode and a drain electrode at both ends of the semiconducting nano-wire; forming at least one ferroelectric nano-structure on the semiconducting nano-wire to form at least one junction; forming an insulation layer on the semiconducting nano-wire and the ferroelectric nano-structure; and forming at least one gate electrode on the insulation layer.

According to a further aspect of the invention, there is provided a method of fabricating a nano electronic device, the method comprising the steps of: forming at least one ferroelectric nano-structure and at least one semiconducting nano-wire on the substrate so as to be adjacent to each other; forming a source electrode and a drain electrode at both ends of the semiconducting nano-wire; and forming at least one gate electrode at a position to be able to induce polarization to the ferroelectric nano-structure.

In the method of fabricating a nano electronic device, the semiconducting nano-wire may be formed of one fabricated in the form of a nano-wire, or may be formed through patterning on a substrate. In addition, the method may further comprise a heat-treating step after forming a source electrode and a drain electrode.

The formation of the ferroelectric nano-structure may include the steps of forming a fibrous potassium titanate and reacting the potassium titanate with a material containing an alkaline earth metal. It is preferable that the ferroelectric nano-structure is formed of a perovskite barium titanate. More specifically, the potassium titanate may include potassium tetratitanate or potassium hexatitanate.

### DESCRIPTION OF DRAWINGS

Further objects and advantages of the invention can be more fully understood from the following detailed description taken in conjunction with the accompanying drawings in which:

FIGS. 1 and 2 are schematic diagrams showing a nano electronic device according to an embodiment of the present invention;

FIGS. 3 and 4 are schematic diagrams showing a nano electric polarization according to an embodiment of the present invention;

FIGS. 5 to 9 are photographs and diffraction patterns of ferroelectric nano-structures used in the fabrication of a nano electronic device according to an embodiment of the present invention;

FIG. 10 is a flowchart showing procedures for forming a ferroelectric nano-structure according to the present invention;

FIG. 11 is an I-V curve of a nano electronic device according to an embodiment of the present invention; and

FIG. 12 is a graph showing a measurement result for stored information in a nano electronic device according to an embodiment of the present invention.

### EXPLANATION OF REFERENCE NUMERALS FOR DESIGNATING MAIN COMPONENTS IN THE DRAWINGS

| | |
|---|---|
| 10: substrate | 20: insulation layer |
| 30: ferroelectric nano-structure | 40: semconducting nano-wire |
| 50a: source electrode | 50b: drain electrode |
| 60: gate voltage | 70: gate electrode |

### MODE FOR INVENTION

The preferred embodiments of the invention will be hereafter described in detail with reference to the accompanying drawings. These embodiments are provided as an illustration to fully convey the spirit of the invention to those skilled in the art. Thus, the present invention is not limited to these embodiments, but may be embodied in other forms. In the drawings, the thickness, length or the like of layers and regions may be exaggerated for convenience. Throughout the description, same reference numerals refer to the same elements.

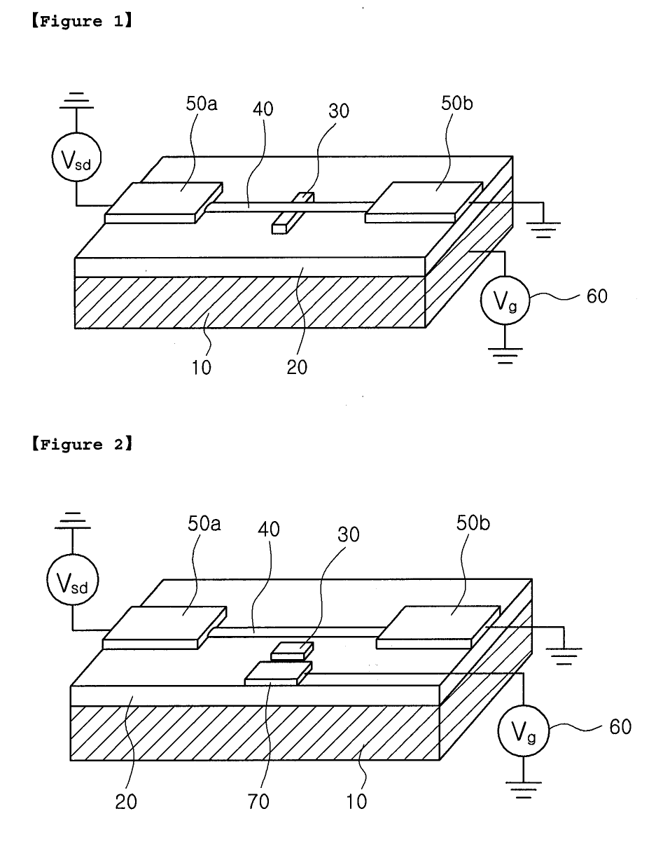

FIGS. 1 and 2 are schematic diagrams showing a nano electronic device according to an embodiment of the present invention.

Referring to FIGS. 1 and 2, the nano electronic device is composed of a ferroelectric nano-structure (30) and a semiconducting nano-wire (40). The ferroelectric nano-structure (30) can be selected from the group consisting of a nano-particle, a nano-rod, and a nano-wire. The semiconducting nano-wire (40) may form a junction with the ferroelectric nano-structure 30, or placed in a distance for electric polarization to be able to be induced in the ferroelectric nano-structure (30) by an electric field. The ferroelectric nano-structure (30) and the semiconducting nano-wire (40) is placed on a substrate (10) having an insulation film (20) formed thereon. In addition, the substrate (10) may be formed of a semiconductor or a metal. The substrate may be provided with a pattern or without a pattern. Furthermore, the substrate (10) may be prepared by forming a metallic film on a semiconductor, or by forming a metallic pattern on a semiconductor. The insulation film (20) includes a silicon oxide film, a silicon nitride film, a metallic oxide film, a metallic nitride film, or the like.

FIG. 1 illustrates a nano electronic device according to the first embodiment of the invention. As illustrated in FIG. 1, the ferroelectric nano-structure (30) and the semiconducting nano-wire (40) form a junction. In this case, a ferroelectric nano-structure is first formed on a substrate and then a semiconducting nano-wire is formed.

According to the second embodiment of the invention, a semiconducting wire is first formed on a substrate, and then a ferroelectric nano-structure is placed on the semiconducting nano-wire so as to form a junction. That is, the position of the semiconducting nano-wire and the ferroelectric nano-structure shown in FIG. 1 is reversed. In addition, an insulation layer is formed on the semiconducting nano-wire and the ferroelectric nano-structure, and a gate electrode is formed on the insulation layer to induce electric polarization in the ferroelectric nano-structure.

FIG. 2 illustrates a nano electronic device according to the third embodiment of the invention. That is, the ferroelectric nano-structure and the semiconducting nano-wire are formed so as to be adjacent to each other. A gate electrode (70) is formed adjacent to the ferroelectric nano-structure.

As shown in FIG. 1, in the case where a ferroelectric nano-structure is first formed and then a semiconducting nano-wire form a junction on top thereof, a gate voltage can be applied to the substrate (10) so that nano electric polarization is formed in the ferroelectric nano-structure (30), and the nano electronic device is operated utilizing the nano electric polarization. In addition, in the case shown in FIG. 2, the gate voltages applied to the gate electrode (70) can cause nano electric polarization in the ferroelectric nano-structure (30) adjacent thereto.

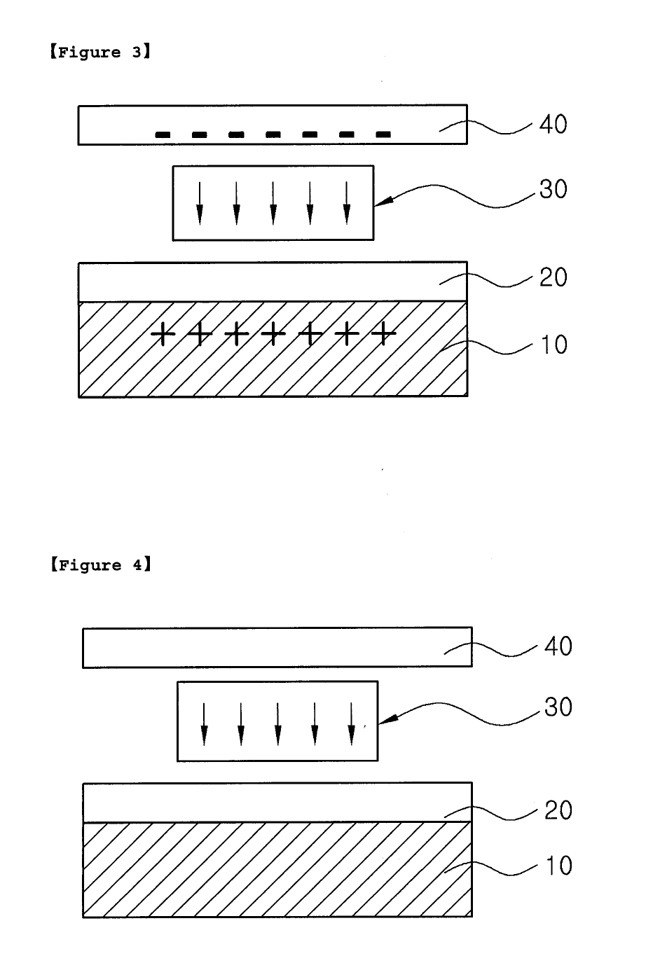

FIGS. 3 and 4 are schematic diagrams showing nano electric polarization of a nano electronic device according to the first embodiment of the invention. A ferroelectric nano-structure is formed on a substrate having an insulation film formed thereon, and a semiconducting nano-wire is formed on the ferroelectric nano-structure to form a junction with each other.

Referring to FIG. 3, if the semiconducting substrate (10) serves as a gate electrode and a gate voltage (60) is applied to the substrate, a certain electric potential difference sets up in between the semiconducting substrate and the semiconducting nano-wire (40) and an electric polarization is formed at the junction area of the ferroelectric nano-structure (30) placed between the substrate (10) and the semiconducting nano-wire (40). This polarization corresponds to a step of “write” of a memory device. Depending on the direction of the electric field caused by the electric potential difference, the polarization in the ferroelectric nano-structure can have two different orientations, which means two states of information. FIG. 3 shows formation of an electric field by a plus voltage applied to the substrate and a minus voltage applied to the semiconducting nano-wire.

Referring to FIG. 4, even after the electric potential difference is removed, the polarization remains in the ferroelectric nano-structure due to its inherent physical property. That is, even if all the voltages are cut off, the “written” state of electric polarization still remains in the ferroelectric nano-structure (30) as it is. If a small electric potential difference is applied between both ends of the semiconducting nano-wire (40) to flow a current, the current is affected by the direction and strength of the surrounding electric field. That is, the “written” electric polarization of the ferroelectric nano-structure (30) makes the semiconducting nano-wire (40) sense the electric field, thereby the written electric polarization affects the current. This phenomenon is corresponding to a step of “read” operation, which is accomplished by measuring the conductivity of the semiconducting nano-wire (40). This characteristics can be utilized in a memory device.

Referring to FIGS. 1 and 2 again, the semiconducting nano-wire (40) may include a silicon nano-wire, and a source electrode (50a) and a drain electrode (50b) may be located at both ends of the semiconducting nano-wire (40). Thus, the voltage applied to the semiconducting nano-wire (40) can be controlled. The voltage of the semiconducting substrate (10) can be used to control the polarization phenomenon along with field effect.

The ferroelectric nano-structure (30) may be formed of a perovskite barium titanate. The ferroelectric nano-structure (30) may have a diameter of 1 nm˜10 μm and a length of 10 nm˜100 μm.

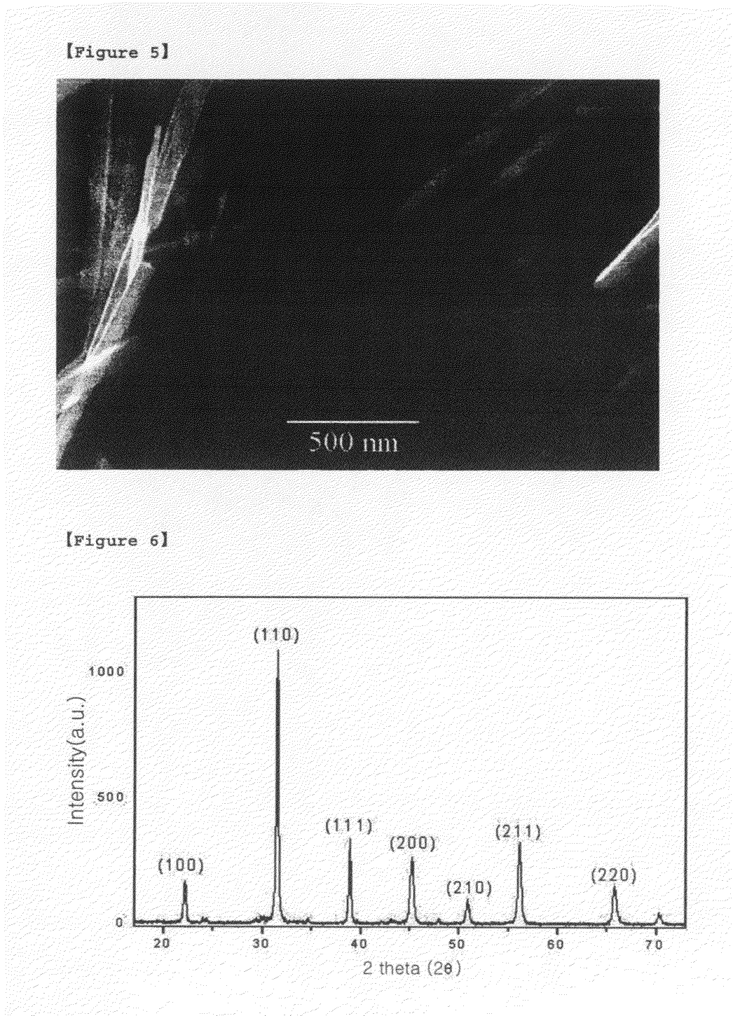

FIGS. 5 to 9 are photographs and diffraction patterns of ferroelectric nano-structures used in the fabrication of a nano electronic device according to an embodiment of the present invention.

Referring to the figures, FIG. 5 shows a scanning electron microscopy (SEM) image of a barium titanate nano-rod. FIG. 6 shows X-ray diffraction patterns of the barium titanate nano-rods. FIG. 7 is a transmission electron microscopy (TEM) image of a single barium titanate nano-rod, which has a rectangular cross-section. FIG. 8 shows a TEM electron diffraction pattern of a barium titanate nano-rod. FIG. 9 is a high-resolution transmission electron microscopy image of a part of a barium titanate nano-rod. The above photographs will be further explained, in conjunction with the following fabricating methods.

Referring FIGS. 1, 2, and 5 to 10, a method of fabricating a nano electronic device according to the present invention.

First, a ferroelectric nano-structure (30) is fabricated. The ferroelectric nano-structure (30) may be formed of a nano-particle, a nano-rode, or a nano-wire. The formation of the ferroelectric nano-structure (30) includes the steps of forming a fibrous potassium titanate, and reacting the potassium titanate with a material containing an alkaline earth metal. Furthermore, the ferroelectric nano-structure may be formed of a perovskite structure of barium titanate.

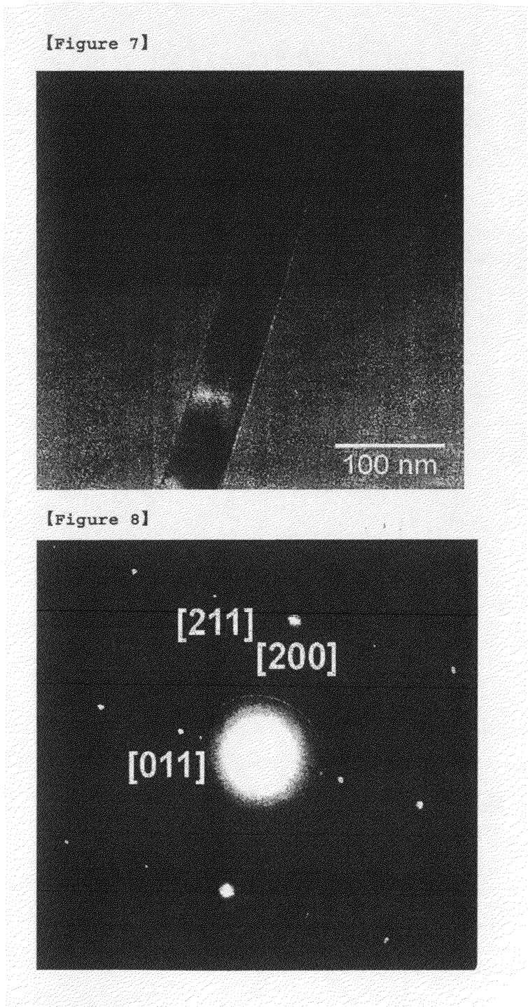

FIG. 10 is a flowchart showing procedures for forming a ferroelectric nano-structure according to the present invention. Referring to the figure, first, in order to form the fibrous potassium titanate (i), a metallic alkoxide such as potassium methoxide (CH₃OK), titanium ethoxide (Ti(OC₂H₅)₄), or the like and ethyl-alcohol are weighed in a desired amount and stirred. Then, an excessive amount of deionized water is added. Thereafter, a mixture of metallic alkoxide, solvent and deionized water is stirred and a hydrolysis reaction and a condensation reaction are carried out (S1). This is sealed and maintained for more than about 100 hrs at room temperature, and then is dried for more than about 48 hrs while maintaining the temperature of around 100° C. (S2). Thereafter, the gel formed through the above steps is heat-treated in a temperature of 700˜900° C. to cause crystallization (S3), thereby forming a nano-structure of potassium titanate series (i).

Then, the step (ii) of reacting the potassium titanate with a material containing an alkaline earth metal will be explained. An appropriate amount of the potassium titanate is dispersed in deionized water (S4). An aqueous solution of barium ions is prepared, using a barium metallic ion specimen such as barium hydroxide octahydrate (Ba(OH)₂.8H₂O) or the like (S5). Thereafter, the deionized water and the aqueous solution are mixed and put into a hydrothermal synthesizer (S6). The ion-exchange reaction of potassium ion and barium ion through the hydrothermal synthesis is performed under a temperature of 70˜100° C. and a pressure of above 5 atms, and for a reaction time of above 48 hrs. Through the above steps, a structural transformation of a perovskite structure of barium titanate can be carried out. Finally, the byproduct K₂O is rinsed away several times using deionized water (S7) and a nano-rod of barium titanate can be obtained through purification.

The ferroelectric nano-structure (30 in FIGS. 1 and 2) formed through the above steps may have a diameter of 1 nm˜10 μm and a length of 10 nm˜100 μm.

In the hydrothermal synthesis explained in FIG. 10, an organic molecule such as surface stabilizer or surfactant or the like is not used, and thus an organic molecular layer does not exist on the surface of the barium titanate nano-rod. This means a favorable merit of fabricating a nano electronic device, as compared with a conventional nano-rod or nano-wire having an organic molecule layer and a cylindrical cross-section. The structural feature (FIG. 7) of having a rectangular cross-section may also be advantageous for the operation of a nano electronic device.

Referring to FIGS. 5 to 9 again, the result of X-ray diffraction measurement clearly shows that a perovskite barium titanate is successfully synthesized through the hydrothermal synthetic process (FIG. 6). In addition, from the structural analysis for crystallinity, it can be seen that the perovskite barium titanate maintains a single crystallinity and has been grown along an axis (FIGS. 8 and 9).

Referring to FIGS. 1 and 2, the ferroelectric nano-structure (30), which is prepared through the above steps, is dispersed on a substrate (10). The ferroelectric nano-structure 30 is crushed and dispersed by means of ultrasonic wave treatment, and then formed on the substrate (10) through a spinning coating. A semiconducting nano-wire (40) is then dispersed on the formed ferroelectric nano-structure (30). Thus, the ferroelectric nano-structure (30) and the semiconducting nano-wire (40) form a junction on the substrate.

In addition, the semiconducting nano-wire (40) and the ferroelectric nano-structure (30) can be disposed and oriented on a desired position, using a method using the flow of a fluid (Science, Vol. 291, 630 page, 2001), a method using a drifting phenomenon on a liquid surface (Nano Lett., Vol. 3, 951, 2003), a DPN (dip-pen nano-lithography) technique for forming a molecular pattern using AFM, or the like.

An insulation film (20) is formed on the substrate (10), which may be a semiconducting substrate (10) or a metallic substrate. The substrate may have a pattern formed thereon, or may have no pattern. In addition, the substrate may be a substrate where a metallic film or a metallic pattern is formed on a semiconductor.

In order to effectively apply an electric field to the semiconducting nano-wire (40), electrodes are attached to both ends of the semiconducting nano-wire (40). That is, a source electrode and a drain electrode (50a and 50b) are formed at both ends of the semiconducting nano-wire (40). The source and drain electrodes (50a and 50b) may be formed of a metal or semiconductor material having a low resistance, and may be formed through lithographic patterning. Furthermore, in order to reduce the contact resistance between the electrodes (50a and 50b) and the semiconducting nano-wire (40), it is preferable that the electrodes (50a and 50b) are heat-treated after formation thereof.

Alternatively, a semiconducting nano-wire (40) can be formed on a substrate, and a ferroelectric nano-structure (30) can be dispersed on the semiconducting nano-wire (40) to form a junction.

As another alternative, as illustrated in FIG. 2, a semiconducting nano-wire and a ferroelectric nano-structure are formed on a substrate so as to be adjacent to each other, and a gate electrode is formed in a position to be able to induce electric polarization in the ferroelectric nano-structure.

A method of fabricating a nano electronic device according to the invention may be summarized as follows.

A method of fabricating a nano electronic device according to an embodiment of the invention comprises the steps of: a) forming a ferroelectric nano-structure on a substrate; b) forming a semiconducting nano-wire on the ferroelectric nano-structure so as to form a junction; and c) forming a source electrode and a drain electrode at both ends of the semiconducting nano-wire. Polarization of the ferroelectric nano-structure can be formed by applying a gate voltage to the substrate.

A method of fabricating a nano electronic device according to another embodiment of the invention comprises the steps of: d) forming a semiconducting nano-wire on a substrate and forming a source electrode and a drain electrode at both ends of the semiconducting nano-wire; e) forming a ferroelectric nano-structure on the semiconducting nano-wire to form a junction; f) forming an insulation layer on the semiconducting nano-wire and the ferroelectric nano-structure; and g) forming a gate electrode on the insulation layer.

A method of fabricating a nano electronic device according to a further embodiment of the invention comprises the steps of: h) forming a ferroelectric nano-structure and a semiconducting nano-wire on the substrate so as to be adjacent to each other; i) forming a source electrode and a drain electrode at both ends of the semiconducting nano-wire; and j) forming a gate electrode at a position to be able to induce polarization in the ferroelectric nano-structure.

In the method according to the invention, the semiconducting nano-wire may be formed through a patterning process. Polarization of the ferroelectric nano-structure can be formed by applying a gate voltage through the gate electrode formed in the step g) or j).

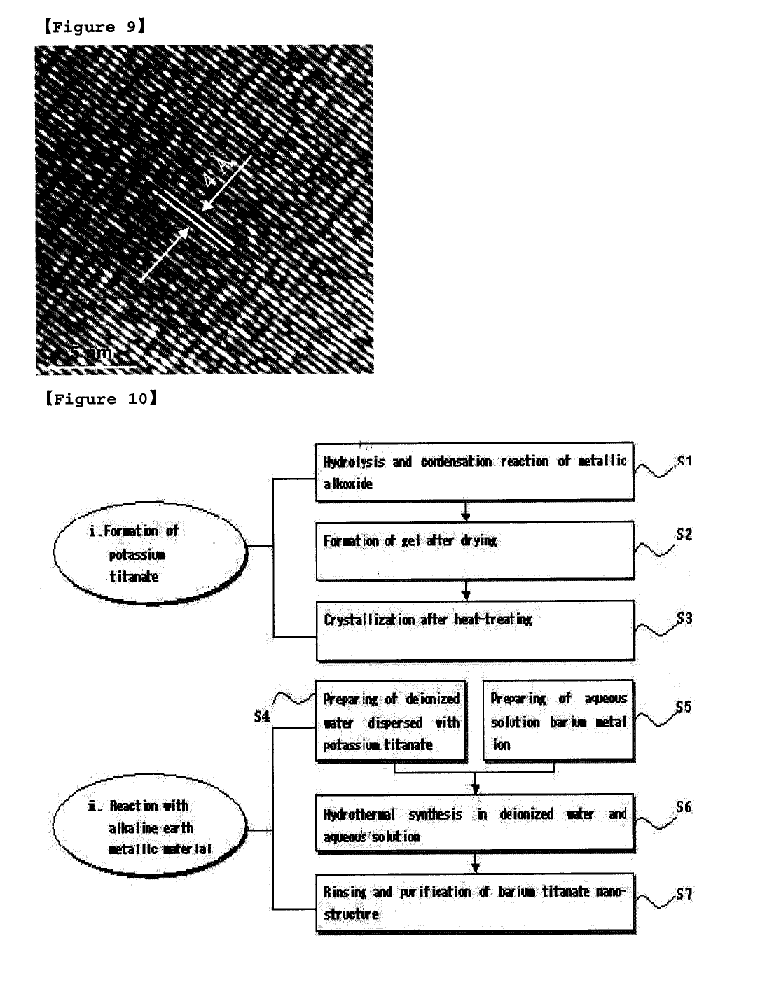

FIG. 11 is an I-V curve of a nano electronic device according to an embodiment of the present invention, which shows the operational result of the nano electronic device. The nano electronic device is fabricated via the steps of forming a nano-structure of barium titanate on the silicon substrate with a silicon oxide film formed thereon and forming a silicon nano-wire on the nano-structure of barium titanate.

Referring to the figure, a certain value of source-drain voltage (V_{sd}) is applied to the nano electronic device and the range of gate voltage (V_{g}) applied to the substrate is controlled. Measuring a change in the source-drain current (I_{sd}) according to the gate voltage results in the I_{sd}-V_{g} curve shown in the figure. This I_{sd}-V_{g} curve is an overlap of the electric field effects from the applied gate voltage (V_{g}) which is exerted directly on the semiconducting nano-wire and from the nano electric polarization which is hold in the ferroelectric nano-structure placed between the semiconducting nano-wire and the substrate.

That is, due to the electric field acting directly on the semiconducting nano-wire, the characteristic of a field effect transistor is exhibited, where the conductivity of the semiconducting nano-wire is changed by the external electric field. That is, the value of source-drain current varies with the change in the gate voltage applied to the substrate. For example, when a plus (+) gate voltage is applied, the current decreases in a p-type semiconducting nano-wire. On the contrary, if a minus (−) voltage is applied, its conductivity increases.

In the case where the gate voltage is applied beyond the critical voltage, the electric polarization of the ferroelectric nano-structure induces a hysteresis on the I_{sd}-V_{g} curve. That is, by the influence of electric polarization formed in the ferroelectric nano-structure, the amount of source-drain current is affected according to the orientation of the electric polarization. If the gate voltage is sufficiently high towards a plus (+) value, the electric polarization of the ferroelectric nano-structure is oriented along the direction of the external electric field. This induced electric polarization remains even after the gate voltage decreases to vanish. The above electric polarization provides an effect similar to the case where a plus (+) gate voltage is being applied to the semiconducting nano-wire. Unless the gate voltage is changed to a sufficiently high minus value, the orientation of the electric polarization in the ferroelectric nano-structure is not reversed. When a gate voltage of above (−) critical voltage is applied, the orientation of the electric polarization in the ferroelectric nano-structure is reversed. Even when the gate voltage becomes zero (0), the amount of current flowing in the semiconducting nano-wire exhibits a different value from the previous one because the polarization provides a similar effect when a (−) gate voltage is being applied. That is, at the gate voltage=0, the current amount depends on the path of the gate voltage application. In other words, when the gate voltage is zero (0), the value of source-drain current becomes different according to the path. Thus a unique hysteresis behavior is exhibited on the I_{sd}-V_{g} curve. At V_{g}=0, the orientation of the electric polarization on the ferroelectric nano-structure determines the amount of current.

As explained above, the fact that the orientation of nano electric polarization can be controlled and that the orientation of the polarization can be detected from the conductivity of the semiconducting nano-wire, means exactly that the nano electronic device can be successfully operated as a memory device.

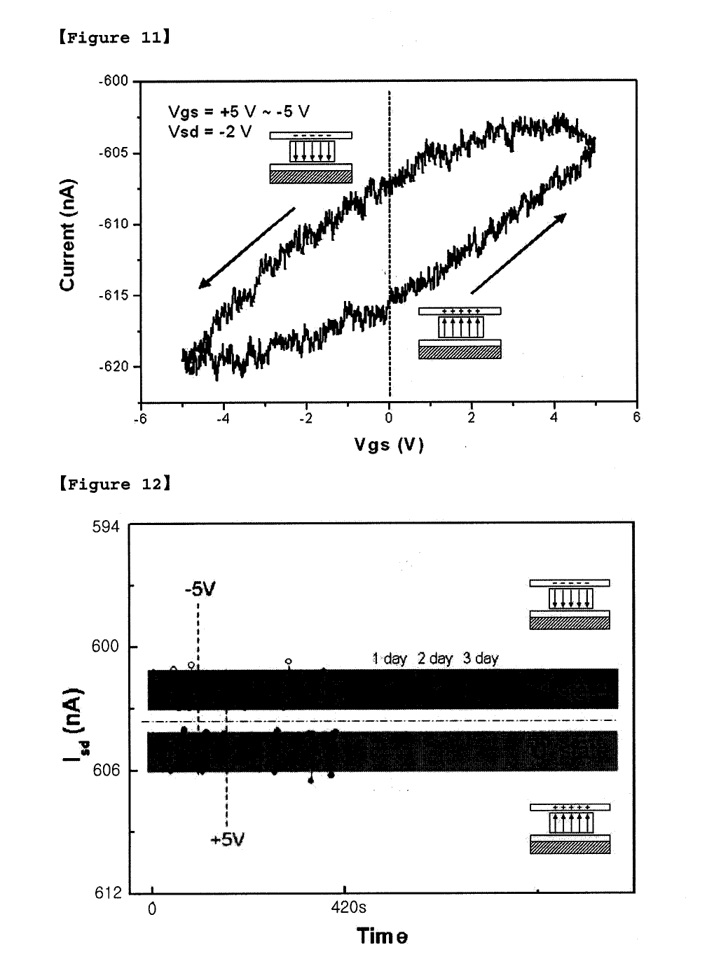

FIG. 12 is shows a result for stored information in a nano electronic device according to an embodiment of the present invention. FIG. 12 further explains the memory operation of the nano electronic device in detail.

Referring to the figure, after measuring source-drain current values at V_{g}=0, a voltage pulse above the critical voltage is applied to the gate. Again, after measuring the source-drain current values at V_{g}=0, a voltage pulse of opposite polarity above the critical voltage is applied to the gate. Then, the step of measuring the source-drain current values at V_{g}=0 is repeated. The application of voltage pulse to the gate is performed in order to reverse the orientation of the electric polarization in the ferroelectric nano-structure. The measurement of the source-drain current is carried out in order to read the state of electric polarization, which is changed by means of the voltage pulse.

From the figure, it can be clearly seen that the orientation of electric polarization can be controlled by applying the voltage pulses and this orientation of nano electric polarization can be read. That is, right after the voltage pulse is applied, the source-drain current value is changed into other state, which can be confirmed through the change in the source-drain current. In addition, it has been found that this electrically polarized state remains in one state after several days. In conclusion, the operational characteristics of the nano electronic device provides a property required for a non-volatile memory device where the state of stored information can be maintained even when the external power is interrupted.

### INDUSTRIAL APPLICABILITY

As apparent from the above description, in the nano electronic device of the present invention, though the structure where a ferroelectric nano-structure and a semiconducting nano-wire form a junction or positioned closely, nano electric polarization is induced in part of the ferroelectric nano-structure, thereby enabling the information storage.

In addition, a ferroelectric material is synthesized into a nano-structure and the nano-structure is controlled to form a junction with a semiconducting nano-wire. Thus, the present invention provides essential technologies and nano materials to fabricate the nano electronic device. That is, a fundamental foundation is provided for commercializing a nano electronic device using electric polarization.

Furthermore, the present invention is applied to an ultra-fine nano memory device using nano-level ferroelectricity, thereby providing technical principles, which can be directly applied to fabrication of a high-density and high capacity non-volatile memory.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

1. A nano electronic device comprising at least one ferroelectric nano-structure and at least one semiconducting nano-wire, wherein at least one polarization formed in the ferroelectric nano-structure is utilized.

2. The nano electronic device according to claim 1, wherein the semiconducting nano-wire forms at least one junction with the ferroelectric nano-structure, or is placed in a distance from the ferroelectric nano-structure so as for electric polarization to be induced in the ferroelectric nano-structure by an electric field.

3. The nano electronic device according to claim 1, wherein the ferroelectric nano-structure is selected from the group consisting of a nano-particle, a nano-rod, and a nano-wire.

4. The nano electronic device according to claim 3, wherein the ferroelectric nano-structure is formed of a perovskite barium titanate.

5. The nano electronic device according to claim 1, wherein the semiconducting nano-wire includes a silicon nano-wire.

6. The nano electronic device according to claim 1, wherein the formed polarization is detected by measuring conductivity of the semiconducting nano-wire.

7. The nano electronic device according to claim 2, including a ferroelectric nano-structure formed on a substrate; a semiconducting nano-wire forms at least one junction on the ferroelectric nano-structure; and a source electrode and a drain electrode formed at both ends of the semiconducting nano-wire, wherein a gate voltage can be applied to the substrate.

8. The nano electronic device according to claim 2, including at least one semiconducting nano-wire formed on a substrate; a source electrode and a drain electrode formed at both ends of the semiconducting nano-wire; at least one ferroelectric nano-structure form at least one junction on the semiconducting nano-wire; an insulation layer formed on the semiconducting nano-wire and the ferroelectric nano-structure; and at least one gate electrode placed on the insulation layer.

9. The nano electronic device according to claim 2, including at least one semiconducting nano-wire and at least one ferroelectric nano-structure formed on a substrate so as to be close to each other, —a source electrode and a drain electrode formed at both ends of the semiconducting nano-wire; and at least one gate electrode formed at a position to be able to induce polarization to the ferroelectric nano-structure.

10. The nano electronic device according to claim 7, wherein the substrate is a substrate having a pattern formed thereon.

11. The nano electronic device according to claim 7, wherein an insulation film is formed on the substrate.

12. The nano electronic device according to claim 7, wherein the semiconducting nano-wire is formed by patterning.

13. A method of fabricating a nano electronic device, the method comprising the steps of:
a) forming at least one ferroelectric nano-structure on a substrate;
b) forming at least one semiconducting nano-wire on the ferroelectric nano-structure so as to form at least one junction; and
c) forming a source electrode and a drain electrode at both ends of the semiconducting nano-wire,
d) wherein a gate voltage can be applied to the substrate.

14. A method of fabricating a nano electronic device, the method comprising the steps of:
d) forming at least one semiconducting nano-wire on a substrate and forming a source electrode and a drain electrode at both ends of the semiconducting nano-wire;
e) forming at least one ferroelectric nano-structure on the semiconducting nano-wire through cross-bonding;
f) forming an insulation layer on the semiconducting nano-wire and the ferroelectric nano-structure; and
g) forming at least one gate electrode on the insulation layer.

15. A method of fabricating a nano electronic device, the method comprising the steps of:
h) forming at least one ferroelectric nano-structure and a semiconducting nano-wire on the substrate so as to be adjacent to each other;
i) forming a source electrode and a drain electrode at both ends of the semiconducting nano-wire; and
j) forming at least one gate electrode at a position to be able to induce polarization to the ferroelectric nano-structure.

16. The method according to claim 13, wherein the semiconducting nano-wire is formed by patterning.
